(19) United States
(12) Patent Application Publication
(10) Pub. No.: US 2025/0249549 A1
(43) Pub. Date: Aug. 7, 2025

(54) Masking System

(71) Applicant: Chromalloy Gas Turbine LLC, Palm Beach Gardens, FL (US)

(72) Inventors: Zachary Oras, Riverview, FL (US); Zachary Hopkins, San Diego, CA (US); Ryan Gilkey, Sparks, NV (US)

(21) Appl. No.: 18/433,679

(22) Filed: Feb. 6, 2024

(51) Int. Cl. B24C 1/04; B24C 1/10

(52) U.S. Cl. CPC B24C 1/04; B24C 1/10

(57) ABSTRACT

A masking system for selectively masking a component includes a mask carrier having a first carrier section and a second carrier section. The masking system has an insert configured to retain the component. The insert has a first insert section and a second insert section. The first insert section and the first carrier section have a first connector set. The first insert section and the second insert section have a second connector set. The first connector set extends in a first direction and removably couples the first insert section to the first carrier section. The second connector set extends in a second direction oblique to the first direction and removably couples the first insert section to the second insert section.

### CROSS REFERENCE TO RELATED APPLICATIONS

None.

### FIELD OF THE DISCLOSURE

The disclosure relates generally to the field of masking systems. More specifically, the disclosure relates to a masking system for masking a part for a media blasting process.

### SUMMARY

The following presents a summary of the invention in order to provide a basic understanding of some aspects of the invention. This summary is not an extensive overview of the invention. It is not intended to identify critical elements of the invention or to delineate the scope of the invention. Its sole purpose is to present some concepts of the invention in a simplified form as a prelude to the more detailed description that is presented elsewhere herein.

In an aspect, a masking system for selectively masking a component includes a mask carrier having a first carrier section and a second carrier section. The masking system has an insert configured to retain the component. The insert has a first insert section and a second insert section. The first insert section and the first carrier section have a first connector set. The first insert section and the second insert section have a second connector set. The first connector set extends in a first direction and removably couples the first insert section to the first carrier section. The second connector set extends in a second direction oblique to the first direction and removably couples the first insert section to the second insert section.

In an aspect, according to any one of the preceding aspects, the first connector set includes a first connector and a second connector, the first connector being part of the first carrier section and the second connector being part of the first insert section.

In an aspect, according to any one of the preceding aspects, the second connector set includes a third connector and a fourth connector, the third connector being part of the first insert section and the fourth connector being part of the second insert section.

In an aspect, according to any one of the preceding aspects, the masking system includes a third connector set associated with each of the first carrier section and the second carrier section, the third connector set extending in the second direction and removably coupling the first carrier section to the second carrier section.

In an aspect, according to any one of the preceding aspects, the masking system includes a fourth connector set associated with the second insert section, the fourth connector set extending in the first direction and removably coupling the second insert section to the second carrier section.

In an aspect, according to any one of the preceding aspects, the first connector set has a male component and a female component.

In an aspect, according to any one of the preceding aspects, the masking system includes a tongue disposed on the first carrier section and a complementary groove disposed on the second carrier section.

In an aspect, according to any one of the preceding aspects, the first carrier section is additively manufactured.

In an aspect, according to any one of the preceding aspects, the masking system is configured to selectively mask the component for a shot peening process.

In an aspect, according to any one of the preceding aspects, the component is a gas turbine component.

In an aspect, according to any one of the preceding aspects, the gas turbine component is a vane.

In an aspect, according to any one of the preceding aspects, the insert is configured to retain the gas turbine component only in one orientation.

In an aspect, according to any one of the preceding aspects, the first carrier section has a semi-cylindrical base and an insert support.

In an aspect, a masking system for selectively masking a component includes an insert having a first insert section and a second insert section. The masking system includes a mask carrier having a first carrier section and a second carrier section. The first carrier section and the second carrier section have a first connector set. The first carrier section and the first insert section have a second connector set. The first connector set extends in a first direction and removably couples the first carrier section to the second carrier section. The second connector set extends in a second direction disparate from the first direction and removably couples the first carrier section to the first insert section.

In an aspect, according to any one of the preceding aspects, the first insert section has a convex projection and the second insert section has a concave channel.

In an aspect, according to any one of the preceding aspects, the first insert section has a tongue and the second insert section has a complementary groove.

In an aspect, according to any one of the preceding aspects, the first direction is oblique to the second direction.

In an aspect, a masking system for selectively masking a component for a shot peening process includes a mask carrier having a first carrier section and a second carrier section. The masking system includes an insert configured to retain the component. The insert has a first insert section and a second insert section. The first insert section and the first carrier section have a first connector set. The first insert section and the second insert section have a second connector set. The first connector set extends in a first direction and removably couples the first insert section to the first carrier section. The second connector set extends in a second direction oblique to first direction and removably couples the first insert section to the second insert section.

In an aspect, according to any one of the preceding aspects, an outermost diameter of the mask carrier is oversized relative to an interior diameter of a can of a shot peen device.

In an aspect, according to any one of the preceding aspects, the component is a gas turbine component.

### BRIEF DESCRIPTION OF THE DRAWINGS

Illustrative embodiments of the present disclosure are described in detail below with reference to the attached drawing figures and wherein:

FIG. 1 is a perspective view of a turbine blade, according to some aspects of the disclosure.

FIG. 2A is an upper perspective view of a turbine vane, according to some aspects of the disclosure.

FIG. 2B is a lower perspective view of the turbine vane shown in FIG. 2A.

FIG. 3A is an upper perspective view of a masking system, according to some aspects of the disclosure, showing the masking system supporting the turbine vane and masking parts of the turbine vane.

FIG. 3B is an upper perspective view of the masking system similar to FIG. 3A, but showing the masking system exploded from the turbine vane, with the masking system including a mask carrier with a pair of carrier sections and a mask insert with a pair of insert sections.

FIGS. 4A and 4B are perspective views of one of the carrier sections shown in FIGS. 3A and 3B, showing a base and an insert support integrally formed with each other.

FIG. 4C is an elevational view of one of the carrier sections shown in FIGS. 3A and 3B.

FIGS. 4D and 4E are top and bottom plan views of the carrier sections shown in FIGS. 3A and 3B, showing the carrier sections attached to one another.

FIG. 4F is a bottom plan view of the carrier sections similar to FIG. 4E, but showing the carrier sections detached from one another by shifting the carrier sections along a mask mating direction.

FIG. 5A is a lower perspective view of a first one of the insert sections shown in FIGS. 3A and 3B.

FIGS. 5B and 5C are front and rear elevational views of the first insert section shown in FIG. 5A.

FIG. 6A is a lower perspective view of a second one of the insert sections shown in FIGS. 3A and 3B.

FIGS. 6B and 6C are front and rear elevational views of the second insert section shown in FIG. 6A.

FIG. 7A is a fragmentary perspective view of the masking system shown in FIGS. 3A and 3B, showing one of the carrier sections removably attached to the first insert section to form a first mated mask assembly.

FIG. 7B is a top plan view of the first mated mask assembly shown in FIG. 7A.

FIG. 7C is a top plan view of the first mated mask assembly similar to FIG. 7B, but showing the carrier section and the first insert section detached from each other by shifting the carrier section and first insert section along a carrier-insert mating direction.

FIG. 8A is a fragmentary perspective view of the masking system shown in FIGS. 3A and 3B, showing one of the carrier sections removably attached to the second insert section to form a second mated mask assembly.

FIG. 8B is a top plan view of the second mated mask assembly shown in FIG. 8A.

FIG. 8C is a top plan view of the second mated mask assembly similar to FIG. 8B but showing the carrier section and the second insert section detached from each other by shifting the carrier section and second insert section along the carrier-insert mating direction.

FIG. 9A is a top plan view of the masking system shown in FIGS. 3A and 3B, showing the first and second mated mask assemblies removably attached to one another.

FIG. 9B is a top plan view of the masking system similar to FIG. 9A but showing the first and second mated mask assemblies detached from one another by shifting the mated mask assemblies along the mask mating direction.

FIG. 10 is a fragmentary upper perspective view of the masking system shown in FIGS. 3A and 3B, showing the turbine vane in engagement with the second mated mask assembly.

FIG. 11 is a fragmentary upper perspective view of the masking system shown in FIGS. 3A and 3B, showing the turbine vane in engagement with the first mated mask assembly.

FIG. 12 is a perspective view of a shot peen apparatus according to some aspects of the disclosure, with the shot peen apparatus including a nozzle and a can.

FIG. 13 is a perspective view of the shot peen apparatus of FIG. 12, showing the masking system and turbine vane supported by the can.

FIG. 14 is a flowchart illustrating a method of making and using a making system, according to some aspects of the disclosure.

### DETAILED DESCRIPTION

A gas turbine engine typically includes a multi-stage compressor coupled to a multi-stage turbine via an axial shaft. Air enters the gas turbine engine through the compressor where its temperature and pressure are increased as it passes through subsequent stages of the compressor. The compressed air is then directed to one or more combustors where it is mixed with a fuel source to create a combustible mixture. This mixture is ignited in the combustors to create a flow of hot combustion gases. These gases are directed into the turbine causing the turbine to rotate, thereby driving the compressor. The output of the gas turbine engine can be mechanical thrust via exhaust from the turbine or shaft power from the rotation of an axial shaft.

The compressor and turbine each include a plurality of rotating blades and stationary vanes having an airfoil extending into the flow of compressed air or flow of hot combustion gases. Each blade or vane has a particular set of design criteria which must be met to provide the necessary work to the flow passing through the compressor and the turbine. However, due to the severe nature of the operating environment, especially in the turbine, it is often necessary to cool these blades and vanes. The blades and vanes often utilize complex internal cooling passageways in order to enhance the efficiency of cooling fluid passing therethrough.

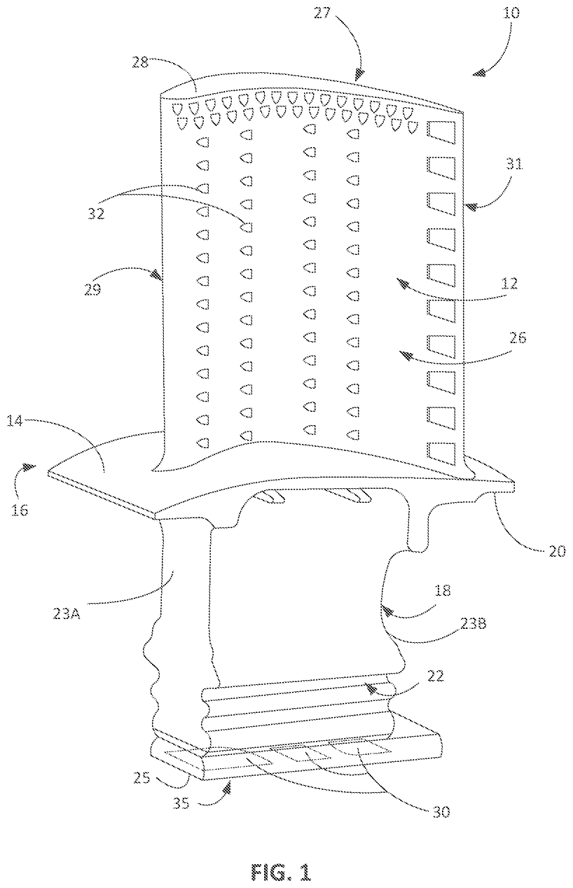

FIG. 1 shows a gas turbine component, such as a gas turbine blade 10. The turbine blade 10 generally includes an airfoil 12 extending from a top or gas path side surface 14 of a platform 16 and a root fixing portion or “dovetail” 18 depending from an undersurface 20 of the platform 16. The dovetail 18 may include one or more serrations or tangs 22 that extend laterally from one side 23A of the dovetail 18 to an opposing side 23B of the dovetail 18. The dovetail 18 may terminate at a terminal or bottom wall 25 that may span between the dovetail sides 23A and 23B. The dovetail 18, including the tangs 22 and the bottom wall 25 thereof, may be adapted for interlocking engagement in a corresponding slot defined in the periphery of a hub of a turbine rotor. The bottom wall 25 may be part of a metering plate 35 that is brazed or otherwise secured to the dovetail 18.

The airfoil 12 may have a pressure side 26, a suction side 27 opposite the pressure side 26, a tip 28, a leading edge 29, and a trailing edge 31. The tip 28 may include or may be configured to interact with a shroud. The shroud may be provided at the tip 28 of each blade 10, or may be a stationary ring including one or more circumferentially extending sections each connected to the gas turbine casing. The shroud(s) may be configured to seal the gap between the tip 28 of the blade 10 and stationary components (e.g., stators) of the turbine, and thereby, may reduce leakage flow between the rotating and stationary components. The airfoil 12, e.g., the pressure side 26 thereof, may come into contact with combustion gases that are at an extremely high temperature. The airfoil 12 or portions thereof may therefore be coated with heat-resistant, wear-resistant, and/or other coatings. During operation, the tip 28 may rub against the tip shroud, and the tip 28 may therefore additionally or alternately be coated with wear-resistant coatings. In like fashion, one or more other portions of the blade 10 may be coated with different materials depending on the environment in which these portions are located and the stresses encountered thereby.

The bottom wall 25 of the dovetail 18 may include one or more air inlet apertures 30. Further, one or more portions of the blade 10 may include cooling holes 32 for cooling the blade 10 during operation. The cooling holes 32 may be provided on one or more surfaces of the airfoil 12, such as the pressure side 26, the suction side 27, the tip 28, the leading edge 29, the trailing edge 31, or a combination thereof. The cooling holes 32 may be circular cooling holes, diffused (e.g., angled) cooling holes, cooling slots, or take on one or more other regular or irregular shapes. Cooling gas may pass through internal cooling channels (not illustrated for ease of description) in the blade 10 and emerge from the cooling holes 32 to create a blanket of thin film over the outer surface of the airfoil 12, thus preventing direct contact of the hot gases and the surfaces of the blade 10. For example, the illustrated blade 10 has air inlet apertures 30 in the bottom wall 25 of the dovetail 18 and cooling holes 32 on the pressure side 26 of the airfoil 12. The blade 10, including the airfoil 12 thereof, may include hollow interior passages for the passage of cooling air, for example, but not limited to, from air inlet apertures 30 to cooling holes 32. Thus, cooling air may be bled from the compressor and channeled into the air inlet apertures 30. This air may exit out the cooling holes 32 to cool one or more portions of the blade 10 during operation. One having skill in the art will understand that different blades may have differing cooling schemes and that the inlet apertures 30 and cooling holes 32 in FIG. 1 are merely exemplary and not intended to be independently limiting.

A gas turbine blade, such as the blade 10, may be manufactured using investment casting, also referred to in the art as lost-wax processing. The investment casting process may involve making a precise negative die of the blade shape that is filled with wax to form the blade shape. If the blade, such as the blade 10, is hollow and has interior cooling passages, a ceramic core in the shape of the cooling passages may be inserted into the middle. The wax blade may be coated with a heat-resistant material to make a shell, and then that shell may be filled with the blade alloy.

Once cast, the blade 10 may undergo one or more finishing processes to prepare the blade 10 for operation. The finishing processes may ensure that the blade 10 has the required aerodynamic profile, as such may impact engine efficiency and fuel consumption. The finishing processes may also make the blade 10 more resistant to fatigue, and thereby increase the lifespan of the blade 10. Some finishing processes may reduce the maintenance requirements associated with the blade 10.

The finishing processes may include one or more of machining the blade 10, coating one or more portions of the blade 10 with heat-resistant, wear-resistant, and/or other suitable coatings, or one or more other processes. In some examples, the finishing processes may include a media blasting process. For example, one or more portions of blade 10 may be media blasted with abrasive media (such as sand or grit) to prepare these portions to receive coating. Alternately or in addition, one or more portions of blade 10 may be blasted with abrasive media to fortify these portions. For example, one or more surfaces of dovetail 18 may be shot peened for fortification.

Shot peening one or more portions of dovetail 18 may be one of the last steps carried out in the production of blades 10. Shot peening is one type of cold-working process that may be used to strengthen the surface of a turbine blade (such as blade 10) or turbine vane. In a shot peening process, metal shots or pellets may be discharged in a stream of pressurized air over the surface of a metal workpiece to plastically deform the surface layer of the workpiece and introduce residual compressive stress therein. The residual compressive stress may reduce the stresses experienced in blade 10 during operation, such as in the rotating environment of the gas turbine engine. Since the shot peening process is carried out at the end of the manufacturing cycle for a typical blade 10, care must be used in the process to avoid damaging blade 10 or incompletely shot peening the intended surfaces thereof. Uniform shot peening of the entire dovetail 18 of blade 10, for example, may ensure enhanced strength of blade 10 during operation and a correspondingly long service life. In conducting a shot peening process, an appropriate masking system may be used so that unintended surfaces are not exposed to or otherwise impacted by the shot peening.

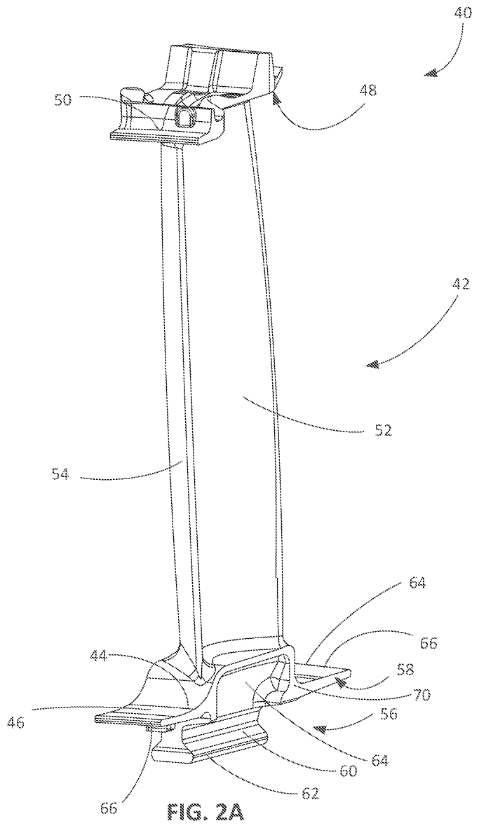

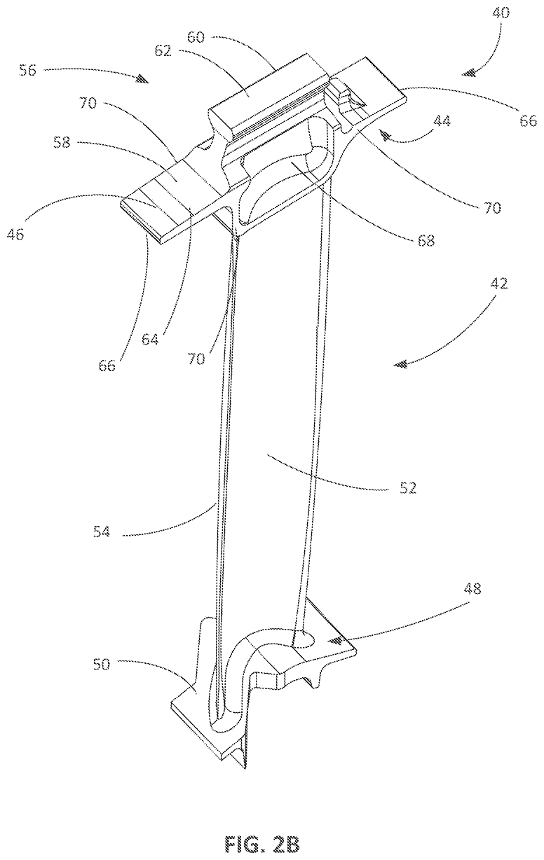

FIGS. 2A and 2B show another gas turbine component, i.e., a gas turbine vane (sometimes referred to as a “bucket” but hereinafter “turbine vane”) 40. The turbine vane 40 generally includes an airfoil 42 extending between a top or gas path inner surface 44 of an inner shroud section 46 and a bottom or gas path outer surface 48 of an outer shroud section 50. Airfoil 42 may include a pressure side 52 and a suction side 54 opposite the pressure side 52. Turbine vane 40 further includes a root dovetail 56 depending from an undersurface 58 of the inner shroud section 46. The dovetail 56 may include one or more serrations or tangs 60 that extend laterally from one side of the dovetail 56 to an opposing side of the dovetail 56. The dovetail 56 may terminate at a terminal or bottom wall 62 that may span between the dovetail sides. The dovetail 56, including the tangs 60 and the bottom wall 62 thereof, may be adapted for interlocking engagement in a corresponding slot defined in a housing of the gas turbine engine. The inner shroud section 46 may include a flange 64 that extends between opposite flange ends 66. The flange 64 may at least partly define undercuts 68 (see FIG. 2B) that are generally centrally located along the flange 64 and formed adjacent the dovetail 56. Flange 64 may also include opposing side faces 70 that cooperate with the flange ends 66 to form a flange perimeter.

The dovetail 56, like the dovetail 18 of blade 10, may be media blasted, e.g., may be shot peened to ensure enhanced strength of vane 40 during operation and a correspondingly long service life. When dovetail 56 is being media blasted in this manner, one or more other portions of vane 40 may be masked to protect these portions from being damaged by the media.

A component of a gas turbine, such as the blade 10, vane 40, or another component, may be media blasted one or more times during manufacture or repair. When only a portion of the component is to be media blasted, the remainder of the component (or a portion of the remainder of the component likely to come into contact with the media) may be masked to reduce the likelihood that the media will impact the remaining surfaces of component. For example, when dovetail 56 of vane 40 is to be media blasted, e.g., shot peened, one or more other portions of vane 40 may be covered or otherwise shielded to preclude damage to these portions from the media blasting process.

When shot peening (or otherwise media blasting) dovetail 56, undersurface 58, and undercuts 68, it may be desirable to seal off or mask other features of the vane 40 (such as airfoil 42) unintended for media blasting. Media may be blasted at the dovetail 56, undersurface 58, and undercuts 68, and if the unintended features are not appropriately masked, media forcibly blasted may damage one or more unintended surfaces of vane 40. It may likewise be desirable to mask portions of vane 40 that are proximate dovetail 56, undersurface 58, and undercuts 68 to preclude damage to these portions by the media.

To avoid unintended damage to vane 40 during media blasting (e.g., shot peening) of dovetail 56, undersurface 58, and undercuts 68, one or more surfaces of vane 40 may be masked using a masking system. A masking system may be manufactured using conventional techniques (such as injection molding). The masking system may be manufactured using rigid and durable materials that can suitably withstand impact of abrasive media. However, rigid masking systems may experience excessive wear or deformation when repeatedly blasted with metal shot during the shot peening process. Conventional rigid masking systems formed with multiple materials (such as a molded mask including a strengthening material) may be unsuitable for components with relatively small features, particularly gas turbine components.

Rigid masking systems manufactured using conventional techniques (e.g., molding) may also be unduly laborious and time-consuming to fabricate. Further, masking systems manufactured using conventional molding techniques may be unideal because of the rigidity of these masking systems. The vane 40, particularly in applications involving repair of vanes, may not be identical to other vanes 40 in the same set. For example, one vane 40 may have a different wear pattern compared to another vane 40 in the same set (e.g., the airfoil 42 of one vane 40 may be worn adjacent the inner shroud section 46 while the airfoil 42 of another vane 40 in the same set may additionally or alternately be worn adjacent the outer shroud section 50). In view of even minor differences between the vanes 40 of the same set, rigid masking systems manufactured using conventional molding techniques may not allow for the same portion(s) of each vane 40 to be exposed or masked for the duration of the media blasting process. For example, a rigid masking system manufactured using conventional molding techniques that suitably masks one vane 40 such that the dovetail 56 thereof is exposed may not suitably mask and leave exposed the same portions of another vane 40 having a slightly different wear pattern. It may be beneficial to mask components (e.g., blades 10, vanes 40, or other components) being media blasted (e.g., shot peened) using masking systems that: (a) suitably mask portions of the component that are not intended to be blasted with media and which have a likelihood of being impacted by the media (e.g., mask airfoil 42 when dovetail 56, undersurface 58, and undercuts 68 of vane 40 are being shot peened); and (b) can conform to different components in the same set (e.g., can conform to different vanes 40 in the same set, notwithstanding minor variations from one vane 40 to the next).

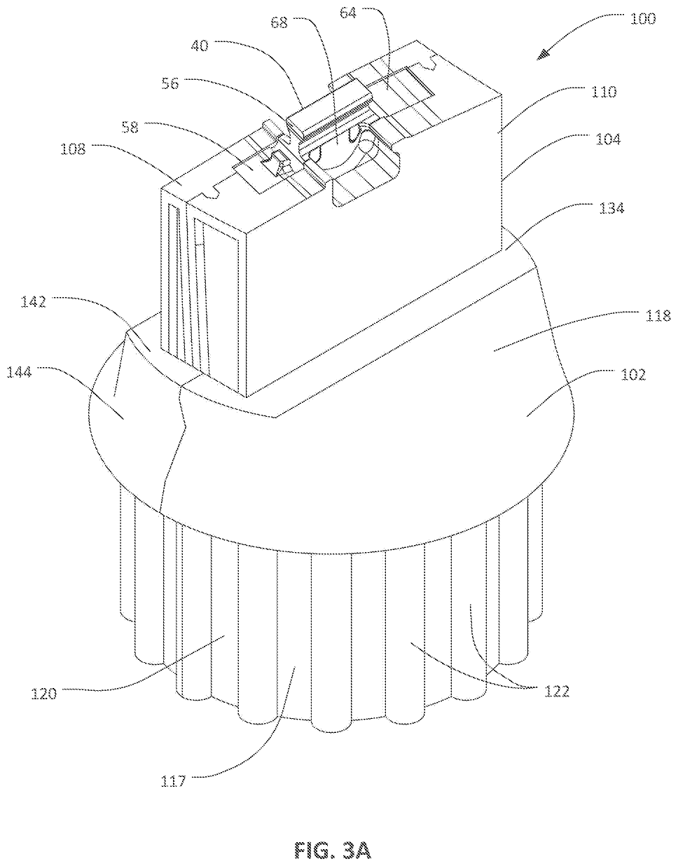

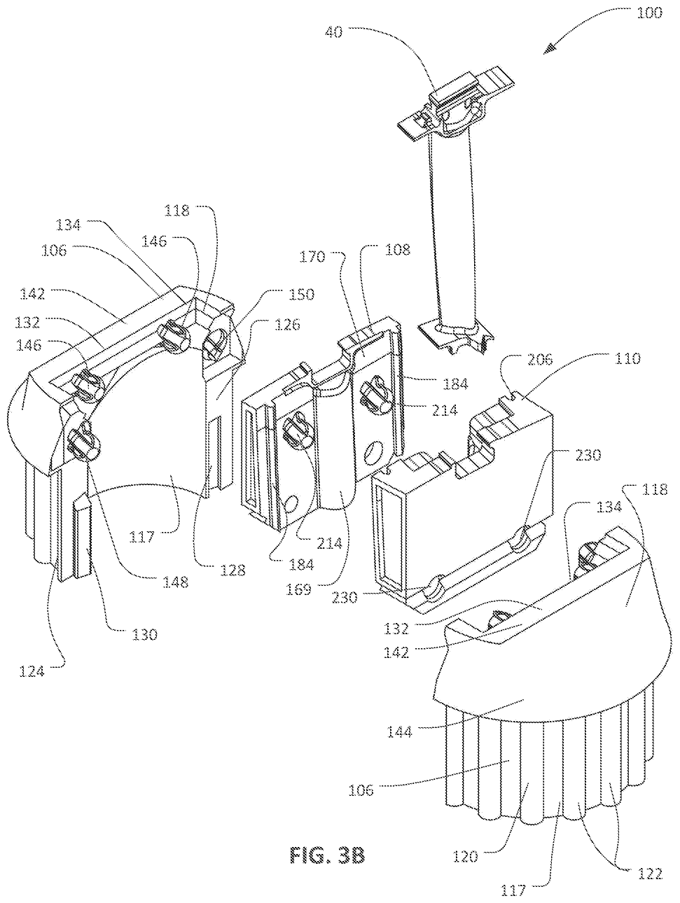

With reference to FIGS. 3A and 3B, a masking system 100, according to some aspects of the disclosure, may be used to mask portions of vane 40 (or other components, such as other turbine components). Masking system 100 may include a universal mask carrier 102 and an interchangeable mask insert 104 that cooperatively serve to mask portions of vane 40 while dovetail 56, undersurface 58, and undercuts 68 remain exposed. Mask carrier 102 of masking system 100 may provide a universal support structure operable to interchangeably support mask insert 104 for masking vane 40, as well as one or more other mask inserts 104 for masking other components. In various examples, the mask carrier 102 and mask insert 104 may include toolless connectors or connecting members (as described below) for removable attachment of the mask carrier 102 and mask insert 104. As used herein, “toolless” connectors may be manually attached to and detached from each other without using a tool to apply force to the connectors. In some examples of the embodiments, mask carrier 102 and mask insert 104 may be additively manufactured using silicone elastomers.

As will be described in more detail, the mask carrier 102 and mask insert 104 may cooperatively support and retain the vane 40 while dovetail 56, undersurface 58, and undercuts 68 are media blasted (e.g. via a shot peening process). According to at least some aspects of the disclosure, masking system 100 may mask all or part of the airfoil 42, inner shroud section 46, and the outer shroud section 50 of vane 40 while the dovetail 56, undersurface 58, and undercuts 68 remain unmasked and exposed to the media. In various examples, the mask carrier 102 and mask insert 104 may be operable to mask one or more alternative portions of the vane 40 or another component.

FIG. 3B shows an exploded view of the masking system 100. Mask carrier 102 may have two opposed carrier sections 106. The two carrier sections 106 may be removably attached to each other to form mask carrier 102 (see FIG. 3A), and mask carrier 102 may removably support and retain the mask insert 104.

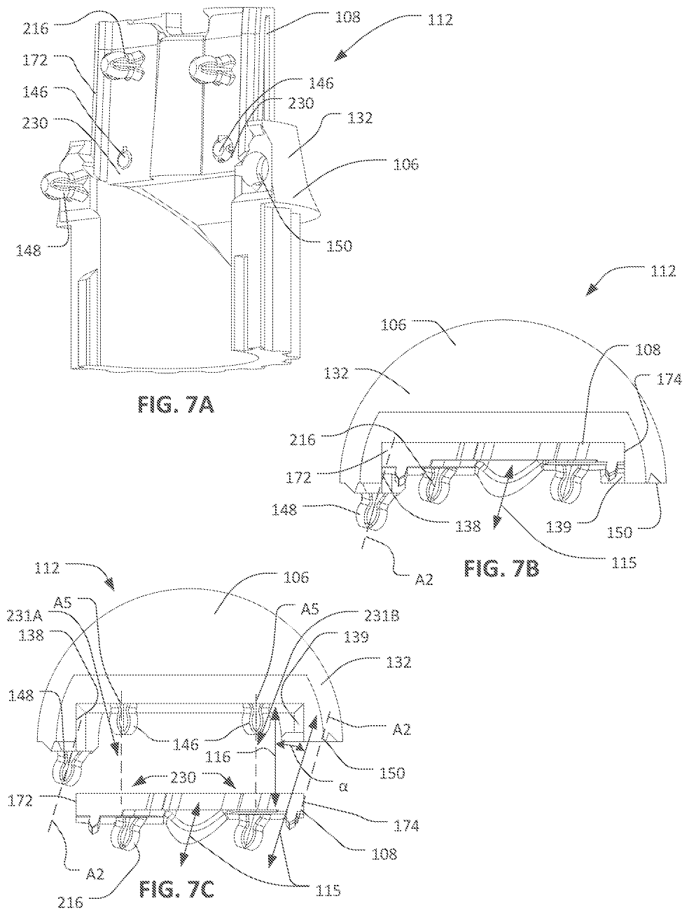

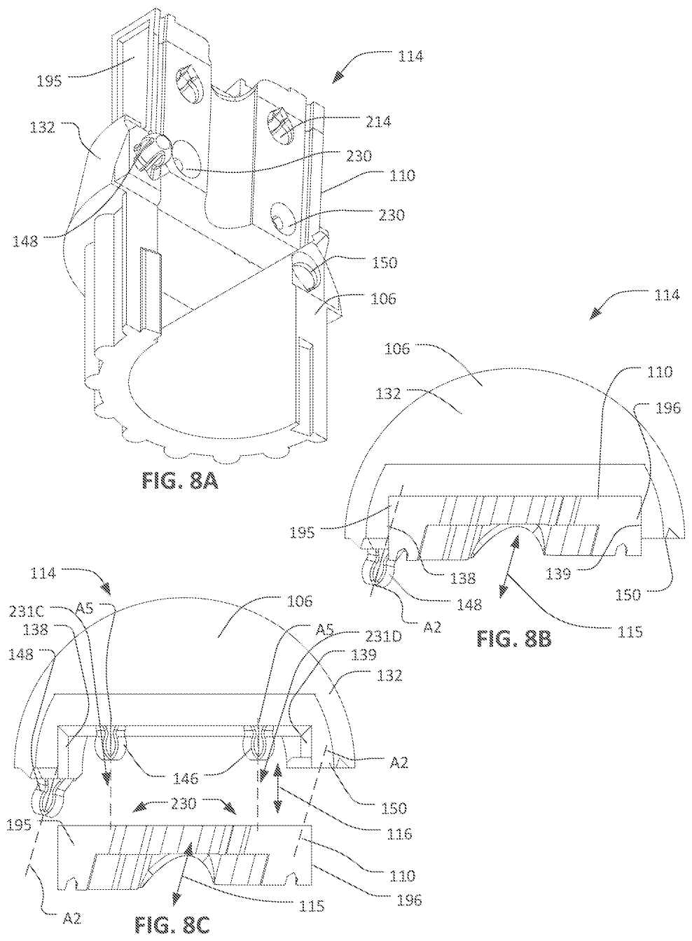

Like mask carrier 102, which includes two opposing carrier sections 106, mask insert 104 may include opposed insert sections 108 and 110. Each of insert section 108 and 110 may be removably attached to and received by a respective carrier section 106. That is, the insert section 108 may be removably attached to one carrier section 106 and the insert section 110 may be removably attached to the other carrier section 106. As discussed below, insert section 108 may be removably attached to one carrier section 106 via connectors or connecting members (hereinafter “connectors”) to form mated mask assembly 112 (FIG. 7A), and insert section 110 may be removably attached to the other carrier section 106 via connectors to form mated mask assembly 114 (FIG. 8A). Thus, one mated mask assembly (such as mated mask assembly 112) may include one carrier section 106 removably coupled to one insert section (such as insert section 108), and the other mated mask assembly (such as mated mask assembly 114) may include the other carrier section 106 removably coupled to the other insert section (such as insert section 110).

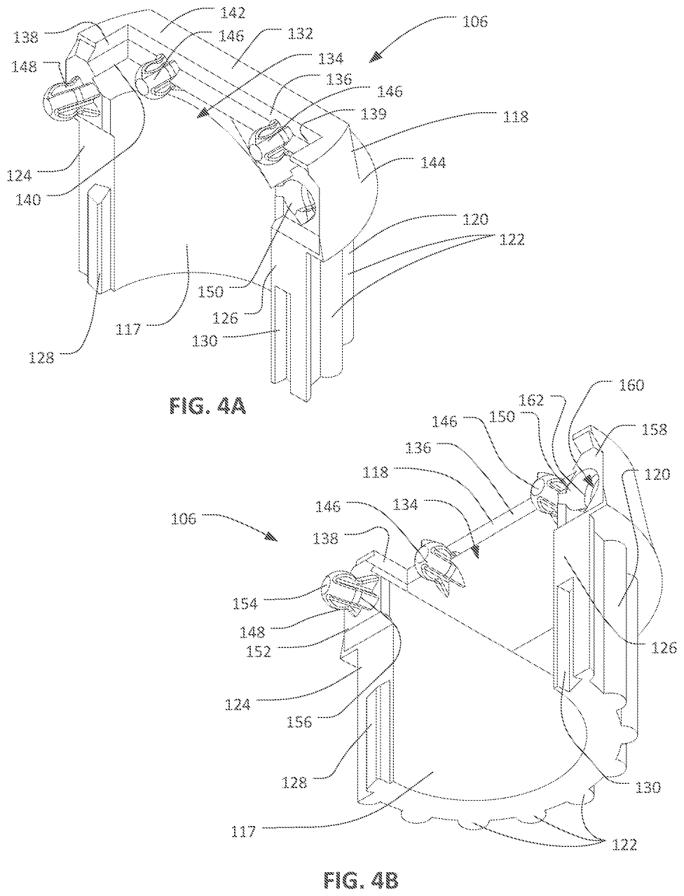

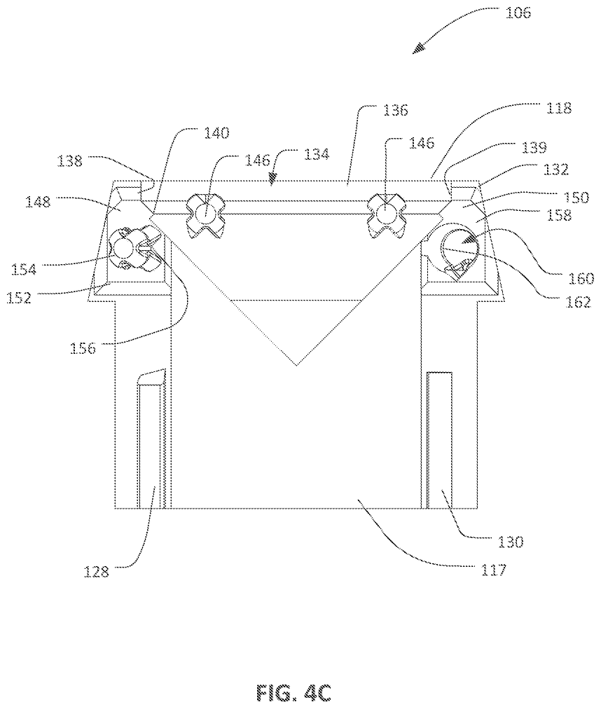

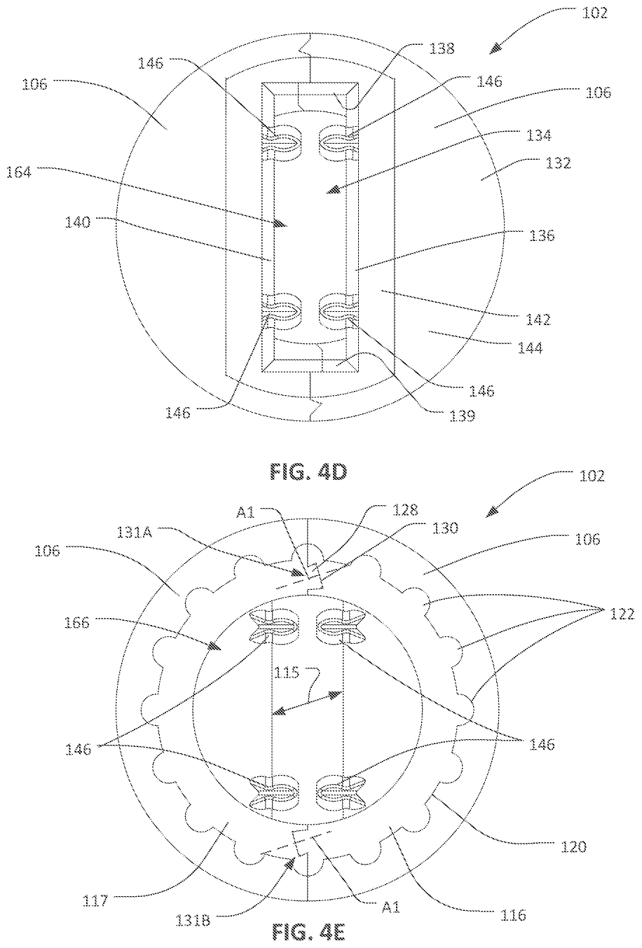

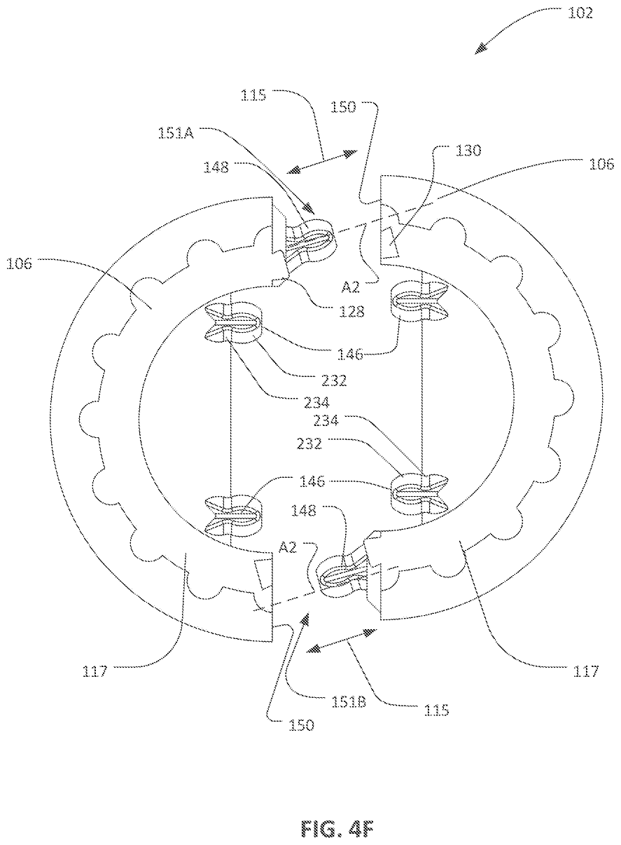

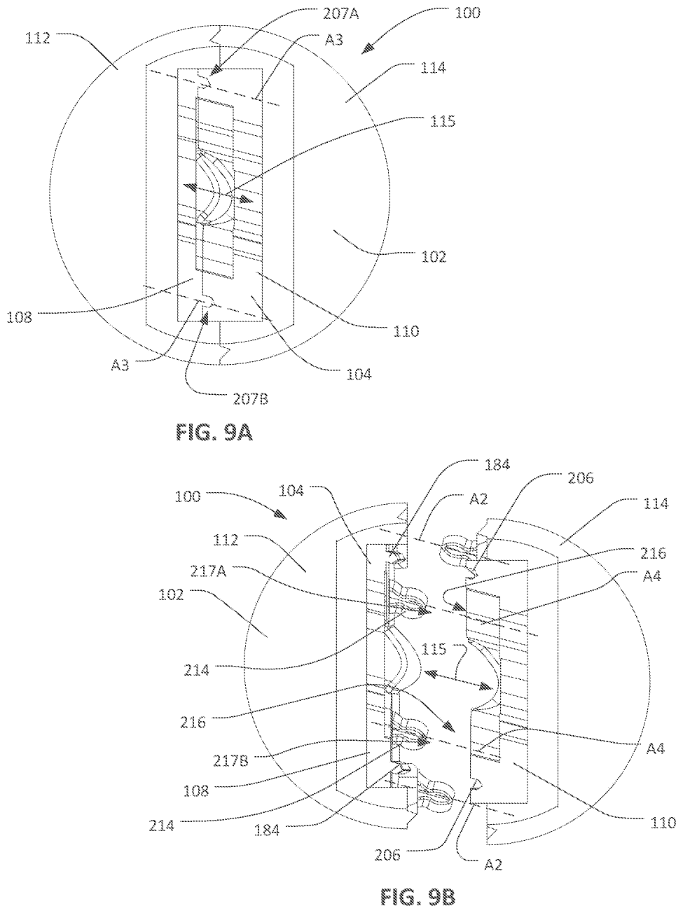

In some aspects of the embodiments, the mated mask assemblies 112 and 114 may be removably attached to one another by connectors that permit separation of the mated mask assemblies 112 and 114 from each other, but without decoupling either insert section 108 and 110 from the respective carrier section 106 to which the insert section 108 and 110 is coupled. As will be described, the carrier sections 106 may be removably attached to each other along a mask mating direction 115 (see FIGS. 4E and 4F), and the insert sections 108 and 110 may also be removably attached to each other along the mask mating direction 115 (see FIGS. 9A and 9B). Consequently, the mated mask assemblies 112 and 114 may be removably attached to each other along the mask mating direction 115 (see FIGS. 9A and 9B). On the other hand, the insert section 108 may be removably attached to one carrier section 106 along a carrier-insert mating direction 116 (see FIGS. 7B and 7C). Similarly, insert section 110 may be removably attached to the other carrier section 106 along the carrier-insert mating direction 116 (see FIGS. 8B and 8C). The mask mating direction 115 and carrier-insert mating direction 116 may be non-parallel and may cooperatively define an oblique angle α (see FIG. 7C). As discussed below, this non-parallel arrangement of the mask mating direction 115 and carrier-insert mating direction 116 may facilitate separation of mated mask assemblies 112 and 114 from each other without decoupling the insert sections 108 and 110 from the respective carrier sections 106. Mask carrier 102 (i.e., each of the two carrier sections 106) and mask insert 104 (i.e., insert section 108 and insert section 110) may be removably attached to one another to cooperatively retain vane 40 so that dovetail 56, undersurface 58, and undercuts 68 may be blasted with media (e.g., shot peened) while one or more other portions of vane 40 are shielded from the media. The ability to remove mated mask assemblies 112 and 114 from each other without disassociating either of insert section 108 or insert section 110 from a respective carrier section 106 may allow for the masking system 100 to be employed to successively mask a plurality of vanes 40 (or other components) with enhanced efficiency.

With reference to FIGS. 4A-4F, mask carrier 102 (FIG. 3A) may include two carrier sections 106 used to removably support and retain the mask insert 104 while also serving to mask portions of the vane 40. In the illustrated example, the two carrier sections 106 are identical. Aspects of the present disclosure, however, include carrier sections 106 that are structurally disparate from each other. As will be explained, the carrier sections 106 may be configured to facilitate removable attachment relative to each other along the mask mating direction 115 (see FIGS. 4E-4F).

In aspects of the disclosure, the mask carrier 102 may be reusable to support any one of multiple mask inserts (such as the mask insert 104 or other mask inserts 104) so that portions of the vane 40 or another suitable component may be masked. That is, the mask carrier 102 may provide a universal carrier structure to support any one of multiple interchangeable mask inserts 104. The mask insert 104, on the other hand, e.g., each of the insert sections 108 and 110, may be part-specific. For example, one mask insert 104 may correspond to vane 40 and another mask insert 104 may correspond to blade 10, and each of these mask inserts 104 may be interchangeably used with the same mask carrier 102 to respectively and selectively mask the vane 40 and the blade 10.

Each of the two carrier sections 106 may include a base 117 (see FIGS. 4A and 4B) and an insert support 118 integrally formed with each other. In some examples, the base 117 may have a generally semi-cylindrical shape. In other examples, the base 117 may have a rectangular, pyramidal, or other symmetric or asymmetric shape. The base 117 may include corrugated outer surface 120 formed partly by upright ridges 122 (see FIGS. 4A and 4B). Each carrier section 106 may also include spaced apart end margins 124 and 126 (see FIGS. 4A and 4B). End margin 124 of each carrier section 106 may include a tongue 128, and end margin 126 of each carrier section 106 may include a groove 130.

According to aspects of the disclosure, tongue 128 and groove 130 may extend along and be integrally formed with the base 117. The tongue 128 and groove 130 may be complementally shaped to serve as toolless connectors that permit removable meshing engagement of the two carrier sections 106. For example, the tongue 128 of one carrier section 106 may engage the groove 130 of the other carrier section 106 to cooperatively provide a connector set 131A (see FIG. 4E), while the groove 130 of the one carrier section 106 may engage the tongue 128 of the other carrier section 106 to cooperatively provide a connector set 131B. In various aspects, the tongue 128 and groove 130 may have complemental dovetail profile shapes (see FIG. 4E) that mesh with each other and cooperatively restrict unintended separation of the two carrier sections 106. In addition to being toolless, the tongue-and-groove construction may restrict media (such as shot) from being wedged between the two carrier sections 106 and driving these carrier sections 106 apart.

In other non-limiting examples, the carrier sections 106 may have an alternative tongue-and-groove configuration to facilitate meshed engagement. For instance, the tongue 128 and groove 130 may be alternatively shaped (e.g., the tongue 128 and groove 130 may have alternative complemental profile shapes, such as a curved or rectangular profile). In various examples, the tongue 128 and groove 130 may be alternatively positioned relative to the end margins 124 and 126. In certain non-limiting examples, the carrier sections 106 may be devoid of tongue 128 and groove 130.

In some examples, tongue 128 and groove 130 of one carrier section 106 may be respectively oriented relative to the groove 130 and tongue 128 of the other carrier section 106 to facilitate meshed engagement and disengagement of the two carrier sections 106 along the mask mating direction 115 (see FIG. 4F). The cross-sectional profiles of tongue 128 and groove 130 may each define an axis of symmetry A1 (see FIG. 4E) that is generally parallel to the mask mating direction 115.

According to certain aspects of the disclosure, the insert support 118 (see FIG. 4A) of each carrier section 106 may be operable to removably receive and retain the mask insert 104. For example, insert support 118 of one carrier section 106 may removably support insert section 108 of mask insert 104, and insert support 118 of the other carrier section 106 may removably support insert section 110 of mask insert 104. Insert support 118 of one carrier section 106 may include an insert mounting wall 132 (see FIG. 4A) that conforms to and removably supports the insert section 108, and the insert support 118 of the other carrier section 106 may include an identical insert mounting wall 132 that conforms to and removably supports the insert section 110.

Insert mounting wall 132 of each carrier section 106 may include an insert opening 134 defined by a longitudinal face 136 and end faces 138 and 139 (see FIG. 4A). Faces 136, 138, and 139 may cooperatively form a locating projection 140 (see FIG. 4C) that extends along the interior perimeter of the insert mounting wall 132. Insert mounting wall 132 may further include an upper surface 142 and an outer surface 144 (see FIG. 4A) that extend about the insert opening 134 to deflect media (such as shot) away from the insert opening 134.

Each carrier section 106 may also include carrier-insert mating connectors 146 (see FIGS. 4A-4B) that extend from the respective face 136. The carrier-insert mating connectors 146 may be configured for the removable coupling of a carrier section 106 to an insert section (e.g., insert section 108 or 110). For example, each carrier section 106 may include two (or a different number, such as one, three, four, et cetera) carrier-insert mating connectors or male components, hereinafter carrier-insert mating connectors 146. As will be described, the carrier-insert mating connectors 146 of one carrier section 106 may be operable for removable attachment of insert section 108 of mask insert 104 to the one carrier section 106, and carrier-insert mating connectors 146 of the other carrier section 106 may be operable for removable attachment of the other insert section 110 of mask insert 104 to the other carrier section 106. The carrier-insert mating connectors 146 of the two carrier sections 106 may therefore be collectively configured for removable attachment of the mask insert 104.

Each carrier section 106 may further include one male carrier connector or male component, hereinafter male carrier connector 148 (see FIG. 4A) and one female carrier connector or female component, hereinafter female carrier connector 150. In other examples, additional male and female carrier connectors 148 and 150 may be provided. Each of the male carrier connector 148 and the female carrier connector 150 of one carrier section 106 may be configured for the removable coupling of that carrier section 106 to the other carrier section 106. For example, the male carrier connector 148 and the female carrier connector 150 of one carrier section 106 may be respectively complementally shaped with the female carrier connector 150 and the male carrier connector 148 of the other carrier section 106. The male and female carrier connectors 148 and 150 of one carrier section 106 may be integrally formed with the insert support 118 of that carrier section 106. In some examples, male and female carrier connectors 148 and 150 may be complementally shaped to provide toolless carrier connectors, with male carrier connector 148 including a projection and female carrier connector 150 including a socket.

Male carrier connector 148 may include a platform 152 (see FIGS. 4B and 4C), a generally spherical end 154, and a neck 156. Female carrier connector 150 may include a recessed surface 158 (see FIGS. 4B and 4C), a socket 160 extending from the recessed surface 158, and an annular projection 162 forming part of the socket 160. Platform 152 of male carrier connector 148 and recessed surface 158 of female carrier connector 150 may be complementally shaped. Spherical end 154 of male carrier connector 148 and socket 160 of female carrier connector 150 may also be complementally shaped. The annular projection 162 of female carrier connector 150 may define an opening diameter that is undersized relative to a minimum diameter of the neck 156 of male carrier connector 148. Thus, when the male carrier connector 148 of one carrier section 106 and female carrier connector 150 of the other carrier section 106 are engaged with each other, the annular projection 162 of female carrier connector 150 and neck 156 of male carrier connector 148 may cooperatively urge the spherical end 154 of male carrier connector 148 into engagement with the socket 160 of female carrier connector 150.

Male and female carrier connectors 148 and 150 may be complementally shaped to permit removable meshing engagement of the two carrier sections 106. For example, the male carrier connector 148 of one carrier section 106 may removably engage the female carrier connector 150 of the other carrier section 106 to cooperatively provide a connector set 151A (see FIG. 4F), while the female carrier connector 150 of the one carrier section 106 may removably engage the male carrier connector 148 of the other carrier section 106 to cooperatively provide a connector set 151B. In various aspects of the disclosure, the male and female carrier connectors 148 and 150 may have complemental shapes (see FIG. 4E) that removably mesh with each other and cooperatively restrict separation of the carrier sections 106. Moreover, the male-and-female connector construction may restrict media (such as shot) from being wedged between the carrier sections 106 and from driving the carrier sections 106 apart.

In other non-limiting examples, the carrier sections 106 may have an alternative male-and-female configuration to facilitate meshed connector engagement. For instance, the connectors 148 and 150 may be alternatively shaped (e.g., the connectors 148 and 150 may have alternative complemental profile shapes, such as a curved or rectangular profile). In at least some aspects, the connectors 148 and 150 may be alternatively positioned relative to the end margins 124 and 126. In some examples, instead of or in addition to male and female carrier connectors 148 and 150, a screw that fits within a threaded opening, a nut and bolt, a wire tie, et cetera, may be used to removably couple one carrier section 106 to the other carrier section 106. Also, in certain examples, the carrier sections 106 may be devoid of connectors 148 and 150.

In some examples, male and female carrier connectors 148 and 150 may be oriented to facilitate meshed engagement and disengagement of the two carrier sections 106 along the mask mating direction 115 (see FIG. 4F). The cross-sectional profiles of the connectors 148 and 150 may each define an axis of symmetry A2 that is generally parallel to the mask mating direction 115 (see FIG. 4F). As such, the axis of symmetry A1 (see FIG. 4E) defined by the cross-sectional profiles of tongue 128 and groove 130 may be generally parallel to axis of symmetry A2 (see FIG. 4F) defined by male and female carrier connectors 148 and 150.

As noted, the insert support 118 of each carrier section 106 may include the insert opening 134 (see FIG. 4A). When the two carrier sections 106 are removably attached to each other (such as by engaging the male carrier connector 148, female carrier connector 150, and the tongue 128 of one carrier section 106 respectively with the female carrier connector 150, male carrier connector 148, and groove 130 of the other carrier section 106), the insert openings 134 of the two carrier sections 106 may be aligned so that the insert supports 118 of the two carrier sections 106 cooperatively form a single continuous carrier opening 164 (see FIG. 4D). Carrier opening 164 may be surrounded and defined by the insert supports 118 (see FIG. 4A) of the two carrier sections 106. The bases 117 of the two carrier sections 106 may also cooperate to form a carrier chamber 166 (see FIG. 4E). When the two carrier sections 106 are assembled together with the insert sections 108 and 110, and the vane 40 is retained between the insert sections 108 and 110, the vane 40 and insert sections 108 and 110 may extend through the carrier opening 164 (see FIGS. 4D, 10, and 11). Vane 40 may also extend into the carrier chamber 166 (see FIGS. 4E, 10, and 11).

The two carrier sections 106 may have an identical construction. Male carrier connector 148 and female carrier connector 150 of each carrier section 106 may cooperatively provide a hermaphroditic connector interface that enables the two carrier sections 106 to be identical to one another. Similarly, tongue 128 and groove 130 of each carrier section 106 may cooperatively provide another hermaphroditic connector interface that enables the two carrier sections 106 to be identically constructed. Identical construction of the two carrier sections 106 may provide production efficiencies and simplify use of the masking system 100 (relative to, e.g., a masking system 100 having disparate carrier sections 106). In some examples, however, the carrier sections 106 may have alternative hermaphroditic connector interfaces for attaching the carrier sections 106 relative to one another. In certain examples, carrier sections 106 may have connector interfaces that are not hermaphroditic. Furthermore, certain examples of the mask carrier 102 may have carrier sections 106 that are not identical to one another.

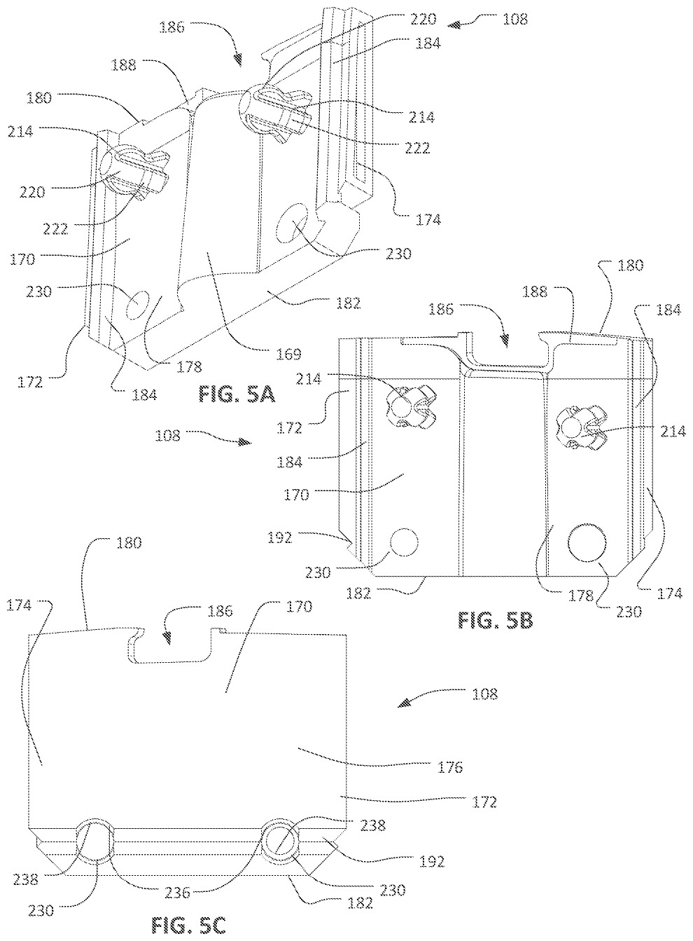

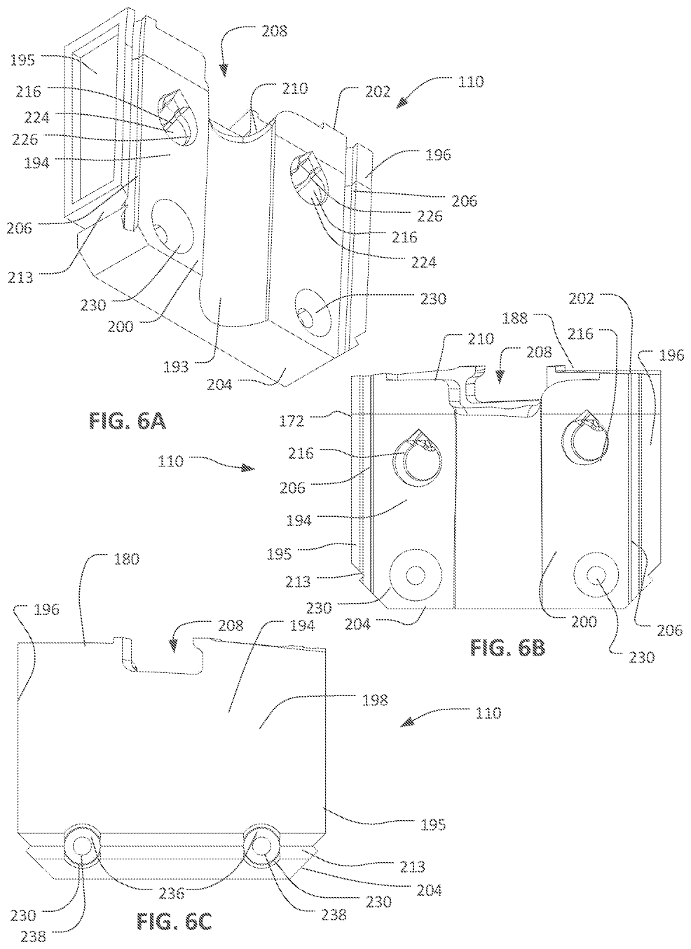

With reference to FIGS. 5A-5C and 6A-6C, mask insert 104 (i.e., each of insert section 108 and insert section 110) may cooperate with mask carrier 102 (i.e., each of the two carrier sections 106) to support and retain the vane 40 (see FIG. 3A) while dovetail 56, undersurface 58, and undercuts 68 of vane 40 are media blasted. The mask insert 104, or one of any other mask inserts 104, may be used interchangeably with the mask carrier 102 to support and mask the vane 40 or another component. The insert sections 108 and 110 of mask insert 104 may be removably attached relative to one another (see FIGS. 9A and 9B) to engage and retain the vane 40 in the masking system 100. In some examples, and as discussed herein, insert sections 108 and 110 may be operable to fit the vane 40 in only one orientation relative to the mask insert 104.

In some examples, insert section 108 (see FIGS. 5A-5C) of mask insert 104 may have a mask wall or structure that engages and supports vane 40. For instance, insert section 108 may have a convex portion or convex projection, hereinafter convex portion 169 (see FIG. 5A), that removably engages and supports the pressure side 52 (see FIGS. 2A and 11) of vane 40. The insert section 108 may include a wall 170 and opposite end portions 172 and 174 integrally formed with insert section 108 (see FIG. 5A-5B). The end portions 172 and 174 of insert section 108 may each have a tongue 184 (see FIG. 5B).

The wall 170 may have an outer mask surface 176 (see FIG. 5C) and an inner mask surface 178 (see FIG. 5A). The outer mask surface 176 may, in some examples, be generally rectangular, though in other examples the outer mask surface 176 may have a cylindrical, conical, or other symmetric or asymmetric shape. Wall 170 may further include a top mask surface 180 (FIG. 5A) and a bottom mask surface 182.

Wall 170 of insert section 108 may include an opening 186 (see FIGS. 5A and 5C) formed in the top mask surface 180. In some examples, wall 170 may include a relief slot 188 that intersects the inner mask surface 178 and top mask surface 180. Wall 170 may further include the convex portion 169. On the outer mask surface 176, adjacent the bottom mask surface 182, the insert section 108 may also include a peripheral groove 192 (see FIG. 5C). Peripheral groove 192 may receive the locating projection 140 (FIG. 4A) of the corresponding carrier section 106.

Insert section 108 may removably support the vane 40. In particular, the relief slot 188 may support and engage flange 64 of vane 40 (see FIG. 11), while convex portion 169 may engage the pressure side 52 (see FIG. 11) of vane 40. Opening 186 of insert section 108 may be aligned with an adjacent one of the undercuts 68 so that the adjacent undercut 68 is unmasked.

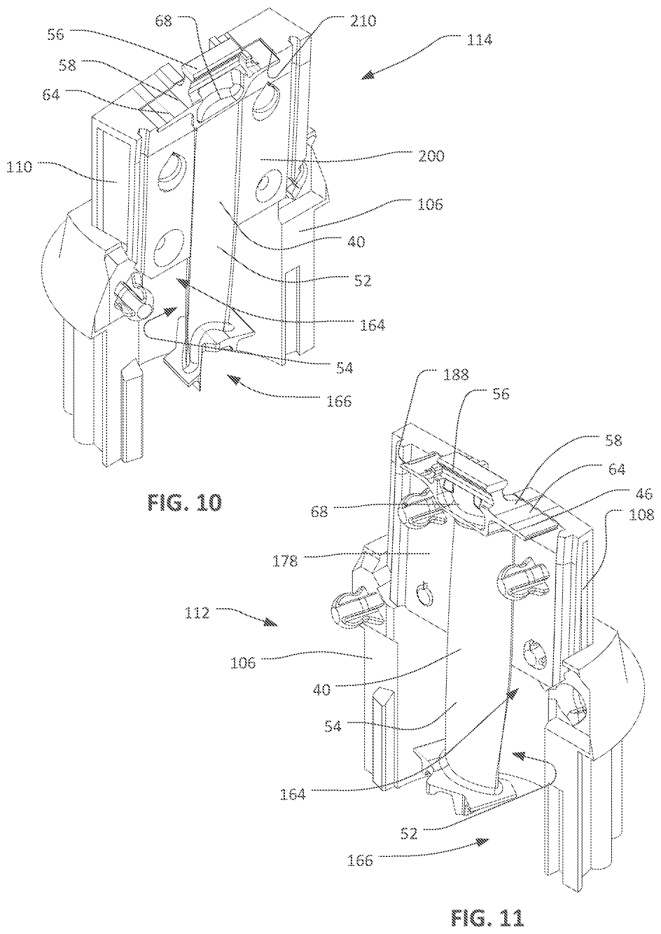

Similar to insert section 108, insert section 110 (see FIGS. 6A-6C) may also have a mask wall or structure that engages and supports vane 40. For instance, insert section 110 may have a concave portion or concave channel, hereinafter concave portion 193 (see FIG. 6A), that removably engages and supports the suction side 54 (see FIGS. 2A and 10) of the vane 40. The insert section 110 may include a wall 194 that extends between opposite end portions 195 and 196 and is integrally formed with insert section 110 (see FIGS. 6A-6C). The wall 194 may have an outer mask surface 198 (see FIG. 6C) with a generally rectangular shape and an inner mask surface 200 (see FIG. 6B). Wall 194 may further include a top mask surface 202 and a bottom mask surface 204 (see FIG. 6C). The end portions 195 and 196 of insert section 110 may each have a groove 206 (see FIG. 6B).

Wall 194 of insert section 110 may include an opening 208. The opening 208 may intersect the top mask surface 202. Wall 194 may include a relief slot 210 that intersects the inner mask surface 200 and top mask surface 202. Wall 194 may further include the concave portion 193 (see FIG. 6A). On the outer mask surface 198 (see FIG. 6C), adjacent the bottom mask surface 204, the insert section 110 may also include a peripheral groove 213 (see FIG. 6C). Peripheral groove 213 may receive the locating projection 140 of the corresponding carrier section 106.

Insert section 110, like insert section 108, may removably support the vane 40. In particular, the relief slot 210 of insert section 110 may support and engage flange 64 of vane 40, while concave portion 193 of insert section 110 may engage the suction side 54 (see FIGS. 2A and 10) of vane 40.

In some examples, the insert sections 108 and 110 of mask insert 104 may fit the vane 40 in only one orientation relative to the mask insert 104. In at least some examples, convex portion 169 of insert section 108 may correspond to and engage the pressure side 52 of vane 40 while the concave portion 193 of insert section 110 may correspond to and engage the suction side 54 of vane 40. Such may ensure that each of a plurality of vanes 40 (or other components) is selectively masked by masking system 100 in the same way.

Each of the two tongues 184 (see FIG. 5B) of insert section 108 and each of the two grooves 206 (see FIG. 6B) of insert section 110 may be complementally shaped to serve as toolless connectors that permit removable meshing engagement of insert sections 108 and 110. For example, each tongue 184 of insert section 108 may removably engage a respective groove 206 of insert section 110 (see FIGS. 9A and 9B) to provide connector sets 207A and 207B (see FIG. 9A). In various aspects, each tongue 184 and groove 206 may have complemental profile shapes (see FIGS. 9A and 9B) that mesh with each other and cooperatively restrict relative movement of the insert sections 108 and 110. Similar to the tongue 128 and groove 130 of carrier sections 106, tongue 184 and groove 206 may have a tongue-and-groove construction that restricts media (such as shot) from being wedged between the insert sections 108 and 110 and driving the insert sections 108 and 110 apart.

In other examples, the insert sections 108 and 110 may have an alternative tongue-and-groove configuration to facilitate meshed engagement. For instance, the tongue 184 and groove 206 may be alternatively shaped (e.g., the tongue 184 and groove 206 may have alternative complemental profile shapes, such as a curved or rectangular profile). In various examples, each tongue 184 may be alternatively positioned relative to the end portions 172 and 174, and each groove 206 may be alternatively positioned relative to end portions 195 and 196. In certain examples, the insert sections 108 and 110 may be devoid of tongue 184 and groove 206.

Tongue 184 and groove 206 may be oriented to facilitate meshed engagement and disengagement of the insert sections 108 and 110 along the mask mating direction 115 (see FIGS. 9A and 9B). The cross-sectional profiles of tongue 184 and groove 206 may each define an axis of symmetry A3 that is generally parallel to the mask mating direction 115 (see FIG. 9A). Thus, the axis of symmetry A3 defined by the cross-sectional profiles of tongue 184 of the insert section 108 and groove 206 of insert section 110, the axis of symmetry A1 (see FIG. 4E) defined by the cross-sectional profiles of tongue 128 and groove 130 of carrier sections 106, and the axis of symmetry A2 (see FIG. 4F) defined by male and female carrier connectors 148 and 150 of carrier sections 106, may each be generally parallel to one another.

Referring again to FIGS. 5A-5C and 6A-6C, insert sections 108 and 110 may be movable into and out of engagement with each other. In particular, insert sections 108 and 110 may be movable into and out of engagement along the mask mating direction 115 (see FIGS. 9A and 9B). In some examples, insert section 108 may include male connectors or male components, hereinafter male connectors 214 (see FIG. 5A) and insert section 110 may include female connectors or female components, hereinafter female connectors 216 (see FIG. 6A). The male connectors 214 may be integrally formed with the corresponding wall 170 (see FIG. 5A) and the female connectors 216 may be integrally formed with the corresponding wall 194 (see FIG. 6A). The male and female connectors 214 and 216 of insert sections 108 and 110, respectively, may be complementally shaped to provide toolless connectors.

In some aspects of the disclosure, male connectors 214 of insert section 108 may each include a generally spherical end 220 and a neck 222 (see FIG. 5A). Female connectors 216 of insert section 110 may each include a socket 224 and an annular projection 226 forming part of the socket 224 (see FIG. 6A). Spherical ends 220 of male connectors 214 of insert section 108 and sockets 224 of female connectors 216 of insert section 110 may be complementally shaped. Also, the annular projection 226 of female connectors 216 of insert section 110 may define an opening diameter that is undersized relative to a minimum diameter of the neck 222 of male connector 214 of insert section 108. Thus, when the male connectors 214 and female connectors 216 are engaged with each other, the annular projection 226 and neck 222 cooperatively urge the spherical end 220 into engagement with the socket 224.

In various aspects, the male and female connectors 214 and 216 may be complementally shaped to permit removable meshing engagement of insert sections 108 and 110. For example, each male connector 214 of the insert section 108 may removably engage a respective female connector 216 of the insert section 110 (see FIG. 9B) to provide connector sets 217A and 217B. Similar to mask carrier 102, the male-and-female connector construction of mask insert 104 may restrict media (such as shot) from being wedged between the insert sections 108 and 110 and driving the insert sections 108 and 110 apart.

In other examples, the insert sections 108 and 110 may have an alternative male—and—female configuration to facilitate meshed connector engagement. For instance, the male and female connectors 214 and 216 may be alternatively shaped (e.g., the male and female connectors 214 and 216 may have alternative complemental profile shapes, such as a curved or rectangular profile). In various examples, the male connector 214 may be alternatively positioned relative to wall 170 and female connector 216 may be alternatively positioned relative to wall 194. In some examples, instead of or in addition to male—and—female connectors 214 and 216, a screw that fits within a threaded opening, a nut and bolt, a wire tie, et cetera, may be used to removably couple the insert sections 108 and 110. In certain examples, the insert sections 108 and 110 may be devoid of male and female connectors 214 and 216.

Male and female connectors 214 and 216 may be oriented to facilitate meshed engagement and disengagement of the insert sections 108 and 110 along the mask mating direction 115 (see FIGS. 9A and 9B). The cross-sectional profiles of male connectors 214 and female connectors 216 may each define an axis of symmetry A4 (see FIG. 9B) that is generally parallel to the mask mating direction 115. Thus, the axis of symmetry A4 defined by the cross-sectional profiles of male connectors 214 of insert section 108 and of female connectors 216 of insert section 110, the axis of symmetry A3 defined by the cross-sectional profiles of tongue 184 of the insert section 108 and groove 206 of insert section 110, the axis of symmetry A1 (see FIG. 4E) defined by the cross-sectional profiles of tongue 128 and groove 130 of carrier sections 106, and the axis of symmetry A2 (see FIG. 4F) defined by male and female carrier connectors 148 and 150 of carrier sections 106, may each be generally parallel to one another.

With reference to FIGS. 5A-5C, 6A-6C, 7A-7C, and 8A-8C, each insert section 108 and 110 may also include carrier-insert mating connectors or female components, hereinafter carrier-insert mating connectors 230 that facilitate removable attachment of insert sections 108 and 110 to respective carrier sections 106. In some examples, the carrier-insert mating connectors 230 may be female connectors. As discussed herein, the insert section 108 may be removably attached to one carrier section 106 via the carrier-insert mating connectors 230 of the insert section 108 and the carrier-insert mating connectors 146 of the carrier section 106 (FIGS. 7A and 7C). Similarly, the insert section 110 may be removably attached to the other carrier section 106 via the carrier-insert mating connectors 230 of the insert section 110 and the carrier-insert mating connectors 146 of the other carrier section 106 (FIGS. 8A and 8C).

In some examples, carrier-insert mating connectors 230 of insert section 108 may be integrally formed with the wall 170 of insert section 108 and extend from outer mask surface 176 to inner mask surface 178 (see FIGS. 5A-5C). Similarly, carrier-insert mating connectors 230 of insert section 110 may be integrally formed with the wall 194 of insert section 110 and extend from outer mask surface 198 to inner mask surface 200 (see FIGS. 6A-6C).

The carrier-insert mating connectors 230 of the mask insert 104 (i.e., each of insert section 108 and insert section 110) and the carrier-insert mating connectors 146 of the mask carrier 102 (i.e., each of the two carrier sections 106) may be complementally shaped to provide toolless connectors. Each carrier-insert mating connector 146 of each carrier section 106 may include a male connector having a generally spherical end 232 and a neck 234 (see FIG. 4F). Each carrier-insert mating connector 230 of the insert sections 108 and 110 may include a female connector having a bore 236 and an annular projection 238 forming part of the bore 236 (see FIGS. 5C and 6C). Each carrier-insert mating connector 146 of one carrier section 106 may removably engage a respective carrier-insert mating connector 230 of the insert section 108 (see FIGS. 7B and 7C) to provide connector sets 231A and 231B. Similarly, each carrier-insert mating connector 146 of the other carrier section 106 may removably engage a respective carrier insert mating connector 230 of the insert section 110 (see FIGS. 8B and 8C) to provide connector sets 231C and 231D. Spherical ends 232 of carrier-insert mating connectors 146 of the carrier sections 106 and bores 236 of carrier-insert mating connectors 230 of insert sections 108 and 110 may be complementally shaped. Also, the annular projection 238 of carrier-insert mating connectors 230 may define an opening diameter that is undersized relative to a minimum diameter of the neck 234 of carrier-insert mating connectors 146. Thus, when the carrier-insert mating connectors 146 of the mask carrier 102 and the carrier-insert mating connectors 230 of the mask insert 104 are engaged with each other (see FIGS. 7A, 7C, 8A and 8C), the annular projection 238 (see FIG. 5C) and neck 234 (see FIG. 4F) may cooperatively urge the spherical end 232 into engagement with the bore 236. Consequently, the carrier-insert mating connectors 146 and 230 may cooperatively urge the insert sections 108 and 110 into conforming engagement with respective carrier sections 106. The male—and—female connector construction may restrict media (such as shot) from being wedged between the insert sections 108 and 110 and respective carrier sections 106.

In other examples, each carrier section 106 and the corresponding insert section 108 and 110 may have an alternative male—and—female configuration to facilitate meshed connector engagement. For instance, the carrier-insert mating connectors 146 and 230 may be alternatively shaped (e.g., the carrier-insert mating connectors 146 and 230 may have alternative complemental profile shapes, such as a curved or rectangular profile). In various examples, at least one of the carrier-insert mating connectors 230 may be alternatively positioned relative to the respective wall 170 of insert section 108 and wall 194 of insert section 110. Similarly, at least one of the carrier-insert mating connectors 146 may be alternatively positioned relative to the corresponding insert mounting wall 132 of carrier sections 106. In some examples, instead of or in addition to male—and—female carrier-insert mating connectors 146 and 230, a screw that fits within a threaded opening, a nut and bolt, a wire tie, et cetera, may be used to removably couple insert sections 108 and 110 to respective carrier sections 106. In certain examples, at least one of the insert sections 108 and 110 may be devoid of carrier-insert mating connectors 230. Similarly, at least one or both of the carrier sections 106 may be devoid of carrier-insert mating connectors 146.

Carrier-insert mating connectors 146 and 230 may be oriented to facilitate meshed engagement and disengagement of each carrier section 106 and a respective insert section 108 and 110 along the carrier-insert mating direction 116 (see FIGS. 7C and 8C). The cross-sectional profiles of the carrier-insert mating connectors 146 and 230 may each define an axis of symmetry A5 that is generally parallel to the carrier-insert mating direction 116 (see FIGS. 7C and 8C). Thus, the sliding engagement between carrier-insert mating connectors 146 and 230 may urge engagement and disengagement of each insert section 108 and 110 relative to the carrier section 106 along the carrier-insert mating direction 116.

As noted above, the axis of symmetry A4 (see FIG. 9B) defined by the cross-sectional profiles of male connector 214 of insert section 108 and of female connector 216 of insert section 110, the axis of symmetry A3 (see FIG. 9A) defined by the cross-sectional profiles of tongue 184 (see FIG. 9B) of insert section 108 and groove 206 of insert section 110, the axis of symmetry A2 (see FIG. 4F) defined by male carrier connector 148 of one carrier section 106 and female carrier connector 150 of the other carrier section 106, and the axis of symmetry A1 (see FIG. 4E) defined by the cross-sectional profiles of tongue 128 of one carrier section 106 and groove 130 of the other carrier section 106, may each be generally parallel to one another and the mask mating direction 115. This alignment of axes A1, A2, A3, A4 and mask mating direction 115 may enable the carrier sections 106 to be removably attached to each other along the mask mating direction 115 (see FIGS. 4E and 4F), and may further allow the insert sections 108 and 110 to also be removably attached to each other along the mask mating direction 115 (see FIGS. 9A and 9B).

The axis of symmetry A5 (see FIGS. 7C and 8C) and the carrier-insert mating direction 116 may be parallel to one another. This alignment of axis A5 and carrier-insert mating direction 116 may enable the insert section 108 to be removably attached to one carrier section 106 along the carrier-insert mating direction 116, while also enabling the insert section 110 to be removably attached to the other carrier section 106 along the carrier-insert mating direction 116 (see FIGS. 8B and 8C).

In an example of the embodiments, axis A5 and carrier-insert mating direction 116 may be non-parallel relative to the axes A1, A2, A3, A4 and mask mating direction 115. Thus, mask mating direction 115 and carrier-insert mating direction 116 may cooperatively define the oblique angle α (see FIG. 7C). As discussed, insert section 108 may be removably attached to one carrier section 106 to form mated mask assembly 112 (FIG. 7A), and insert section 110 may be removably attached to the other carrier section 106 to form mated mask assembly 114 (FIG. 8A). The non-parallel orientation of the carrier-insert mating direction 116 relative to the mask mating direction 115 may facilitate separation of the mated mask assemblies 112 and 114 from each other along the carrier-insert mating direction 116, but: (a) without decoupling the insert section 108 from the carrier section 106 to which insert section 108 is coupled, and (b) without decoupling insert section 110 from the other carrier section 106 to which insert section 110 is coupled. The non-parallel orientation of the carrier-insert mating direction 116 relative to the mask mating direction 115 may therefore allow for different vanes 40 in the same set to be readily masked using the same masking system 100 without the need to reassemble each insert section 108 and 110 with a respective carrier sections 106.

The faces 138 and 139 of each carrier section 106 may extend parallel to the mating direction 116 (see FIGS. 7C and 8C). Further, end portions 172 and 174 of insert section 108 may include end surfaces that are parallel to faces 138 and 139 and the mating direction 116 (see FIGS. 7B and 7C). End portions 195 and 196 of insert section 110 may include end surfaces that are parallel to faces 138 and 139 and the carrier-insert mating direction 116 (see FIGS. 8B and 8C). As a result, faces 138 and 139 of one carrier section 106 and end portions 172 and 174 of insert section 108 may urge sliding engagement and disengagement of that carrier section 106 and insert section 108 along carrier-insert mating direction 116. Similarly, faces 138 and 139 of the other carrier section 106 and end portions 195 and 196 of insert section 110 may urge sliding engagement and disengagement of that carrier section 106 and insert section 110 along carrier-insert mating direction 116.

In various other examples, carrier sections 106 and insert sections 108 and 110 may have alternative connector elements that restrict decoupling of the insert sections 108 and 110 from the respective carrier sections 106 while allowing for mated mask assemblies 112 and 114 to be detached from each other. Further, the configuration of the carrier sections 106 may allow for insert sections 108 and 110 corresponding to other parts (e.g., vanes other than vane 40, blades, or other components) to be used interchangeably with the same carrier sections 106 to retain and selectively mask these other parts.

Several connector sets, such as connector sets 131A, 131B, 151A, 151B, 207A, 207B, 217A, 217B, 231A, 231B, 231C, and 231D, are disclosed herein. Unless specified otherwise, any one of these connector sets 131A, 131B, 151A, 151B, 207A, 207B, 217A, 217B, 231A, 231B, 231C, and 231D, or another connector set, may be referred to herein as the “first connector set,” the “second connector set,” the “third connector set,” the “fourth connector set,” and so on. Phrases such as the “first connector set,” the “second connector set,” the “third connector set,” “the fourth connector set,” et cetera, are not intended to be limited to a particular connector set, but instead, are used to distinguish any given connector set (such as the “first connector set”) from other connector sets (such as the “second connector set,” the “third connector set,” and so on).

In the same manner, several connectors, such as connectors 146, 148, 150, 214, 216, and 230 are disclosed herein. Unless specified otherwise, any one of these connectors, or another connector (such as tongues 128 and 184 and grooves 130 and 206) may be referred to herein as the “first connector,” the “second connector,” the “third connector,” the “fourth connector,” and so on. Phrases such as the “first connector,” the “second connector,” the “third connector,” “the fourth connector,” et cetera, are not intended to be limited to a particular connector, but instead, are used to distinguish any given connector (such as the “first connector”) from other connectors (such as the “second connector,” the “third connector,” and so on).

Similarly, phrases such as “first direction” and “second direction” are not intended to be limited to a particular direction (such as mask mating direction 115 or carrier-insert mating direction 116) and may be used to distinguish one direction (such as the first direction) from another direction (such as the second direction).

With reference to FIGS. 10 and 11, prior to securing vane 40 between mated mask assemblies 112 and 114, vane 40 may be moved into engagement with one of the mated mask assemblies 112 and 114. For example, vane 40 may be engaged with the insert section 108 of mated mask assembly 112 by positioning the inner shroud section 46 in engagement with the relief slot 188 of the insert section 108 (see FIG. 11). At the same time, pressure side 52 of vane 40 may also engage the convex portion 169 of insert section 108. Similarly, vane 40 may be engaged with the insert section 110 of mated mask assembly 114 by positioning the inner shroud section 46 in engagement with the relief slot 210 of the insert section 110 (see FIG. 10). At the same time, suction side 54 of vane 40 may also engage the concave portion 193 of insert section 110. With the vane 40 positioned in engagement with one of the mated mask assemblies 112 and 114, the vane 40 may be removably secured between the insert sections 108 and 110 by attaching the mated mask assemblies 112 and 114 to one another.

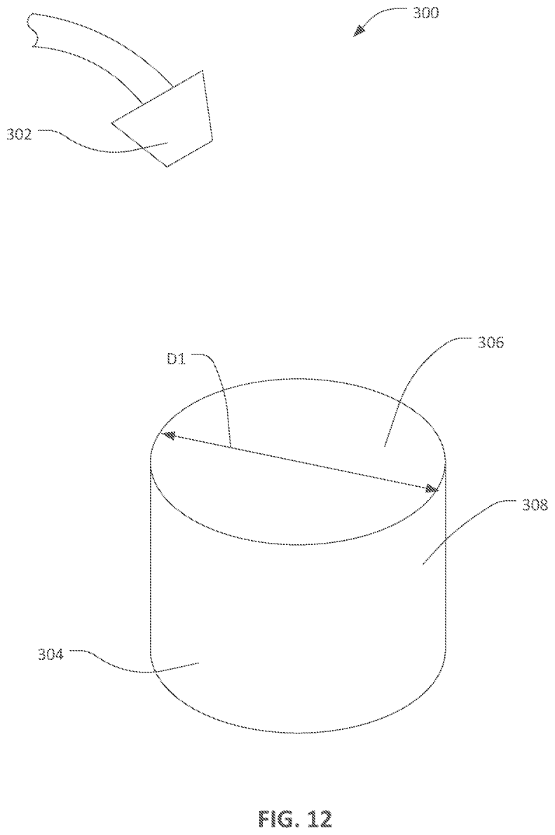

FIG. 12 shows a shot peen apparatus 300, according to an aspect of the disclosure. Shot peen apparatus 300 may have one or more nozzles and one or more cans or holders. The illustrated embodiment has a single nozzle 302 and a single can 304, although additional nozzles and cans may be provided. The can 304 includes an open chamber 306 that is surrounded by an endless side wall 308. A component, such as vane 40, or another component to be shot peened, may be situated in the can 304 while the component is retained by the masking system 100. The nozzle 302 may eject shots at high pressure as the can 304 rotates to allow different surfaces of the component to be bombarded by the media. The shots may strike the component situated in the can 304 and peen exposed surfaces of the component.

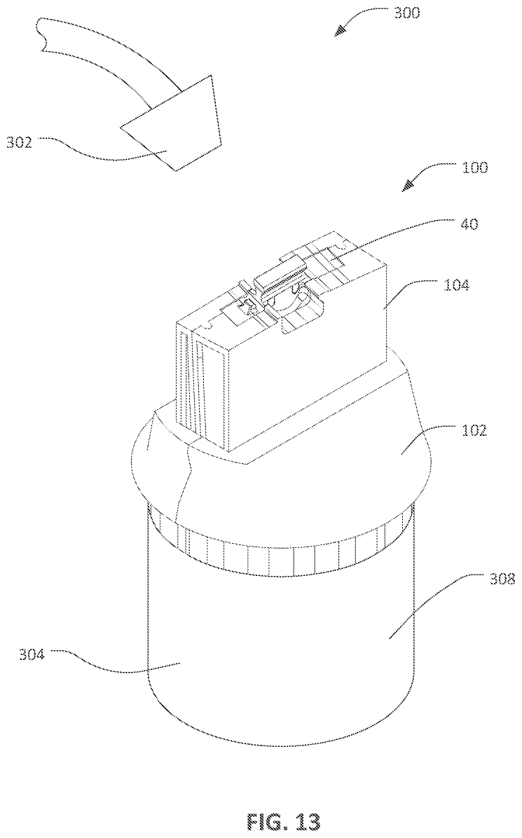

FIG. 13 shows the shot peen apparatus 300 being used to shot peen vane 40. The masking system 100, with the vane 40 retained therein, may be disposed partly within the can 304. The masking system 100 may shield portions of the vane 40 not intended to be shot peened while exposing portions of dovetail 56, undersurface 58, and undercuts 68 (see FIG. 3A) to media.

In preparation for masking the vane 40, insert sections 108 and 110 may be designed and formed specifically for engaging and retaining the vane 40. Carrier sections 106 may be removably attached to respective insert sections 108 and 110 to provide corresponding mated mask assemblies 112 and 114. The insert sections 108 and 110 may then receive the vane 40 and permit attachment of the mated mask assemblies 112 and 114 to one another so that the vane 40 is secured within the masking system 100 and surfaces of vane 40 to be shot peened are exposed.

Once assembled, the vane 40 and masking system 100 may be positioned in the can 304 by inserting the base 117 of mask carrier 102 into the open chamber 306 (see FIG. 12) of the can 304. Side wall 308 of can 304 may have an interior diameter D1 sized to receive the vane 40 retained within the masking system 100. In at least one example, the base 117 may have an outermost diameter that is oversized relative to the interior diameter D1 of the can 304. As the base 117 is inserted into the chamber 306, radially outer portions of the base 117 (such as the upright ridges 122) are operable to be at least partly compressed or squeezed by the side wall 308 of the can 304. Thus, with the base 117 inserted into the can 304, the base 117 may apply pressure against the side wall 308 so that the base 117 and can 304 frictionally engage one another. In this manner, the masking system 100 may be restricted from moving relative to the can 304 while the shot peen apparatus 300 is being used to blast media on the vane 40, thereby increasing consistency of the media blasting operation.

Once a masking system 100 together with a vane 40 is disposed in the can 304, the nozzle 302 may be used to eject shots at a high pressure to peen the surfaces of the dovetail 56, undersurface 58, and undercuts 68. After the shot peening process is complete, the masking system 100 and vane 40 may be removed from the can 304. The mated mask assemblies 112 and 114 of the masking system 100 may be detached from each other, and the vane 40 may be removed. In this manner, masking system 100 may allow for selective masking of a component blasted with abrasive media.

In preparation for masking a second vane 40, the vane 40 may be inserted between the mated mask assemblies 112 and 114. Mated mask assemblies 112 and 114 may then be removably attached to each other to secure the second vane 40 within the masking system 100. Thus, mated mask assemblies 112 and 114 may be uncoupled from each other to disassociate vane 40 from masking system 100, and mated mask assemblies 112 and 114 may be coupled to each other to secure vane 40 (e.g., a second vane 40) within masking system 100, without having to disassociate either insert section 108 or 110 from its respective carrier section 106.

Alternatively, if a component other than vane 40 is to be blasted with media, the insert sections 108 and 110 may be detached from the respective carrier section 106. A second set of insert sections (not shown) designed specifically for engaging and retaining that component may be mated to the carrier sections 106 in place of the insert sections 108 and 110 to provide a modified set of mated mask assemblies 112 and 114. The second set of insert sections 108 and 110 may then receive the component and permit attachment of the modified set of mated mask assemblies 112 and 114 to one another so that the component is secured within the masking system 100.

In some non-limiting examples, one or more portions of the masking system 100, or the entire masking system 100, may be additively manufactured. Additive manufacturing, also referred to as 3D printing, may be performed by dividing the shape of a three-dimensional object, i.e., the masking system 100 in this example, into a number of two-dimensional cross sections having a uniform or variable thickness, and forming the two-dimensional cross sections to be stacked one by one. There are several known additive printing methods such as a material extrusion method, a material jetting method, a binder jetting method, a sheet lamination method, a vat photo-polymerization method, a powder bed fusion method, a directed energy deposition (DED) method, et cetera. Any one or more of these methods, or any other additive manufacturing method, now known or hereinafter developed, may be employed to manufacture the masking system 100, including the carrier sections 106 and the insert sections 108 and 110.

In some examples, the masking system 100 may be manufactured using vat photo-polymerization. Vat photopolymerization, such as stereolithography, direct light processing, continuous liquid interface production, solid ground curing, et cetera, is a category of additive manufacturing processes that create three dimensional objects by selectively curing material (e.g., resin or other photopolymers) through targeted light-activated polymerization. When exposed to certain wavelengths of light, the liquid photopolymers' molecules may rapidly bind together and cure into a solid state through a process called photopolymerization. The liquid photopolymer(s) may be held in a container or vat with the build platform partially submerged near the surface of the liquid. Using the information supplied by a CAD or other design file, the printer may direct a light source to selectively cure the liquid photopolymer into a solid layer. Then the build platform may then be re-submerged into the remaining resin and the process may be repeated for the next layers until the masking system 100 has been fully printed.

In an example of the disclosure, the masking system 100 (e.g., carrier sections 106 and the insert sections 108 and 110) may be additively manufactured using silicone elastomers having a shore hardness in a range between about 50 and about 90A. In some examples, IND402 from Loctite® may be used to additively manufacture masking system 100. In other examples, elastomeric three-dimensional printable polymers (e.g., resins, pellets, filaments, powders, and similar materials) that provide a minimum shore hardness of about 75A, a minimum energy return of about 33%, and a minimum tear strength of about 28 KN/m, may be used to additively manufacture masking system 100.

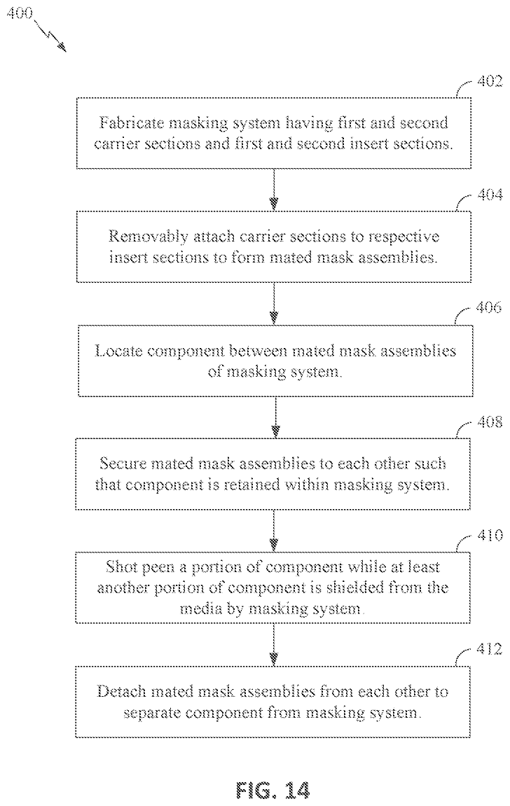

FIG. 14 is a flowchart illustrating a method 400 of making and using the masking systems disclosed herein (e.g., masking system 100) to mask a component (such as vane 40) and blast the component with media. At step 402, a masking system may be fabricated. For example, masking system 100 having two carrier sections 106, and first and second insert sections 108 and 110 may be additively manufactured. In other examples, one or more portions of the masking system 100 may be manufactured using injection molding or other conventional techniques.

At step 404, carrier sections 106 may be removably attached to respective insert sections 108 and 110 to form mated mask assemblies 112 and 114. At step 406, a component may be located between the mated mask assemblies 112 and 114 of the masking system 100. At step 408, the mated mask assemblies may be secured to each other such that the component is retained within the masking system.

At step 410, a portion of component may be shot peened while at least one other portion of the component is shielded from media by the masking system 100. At step 412, once the media blasting process is complete, the mated mask assemblies 112 and 114 may be detached from each other to separate the component from the masking system 100.

While the disclosure illustrates the masking systems (e.g., masking system 100) generally with reference to vane 40, the masking systems disclosed herein may be used to selectively mask other components (such as other gas turbine components including blades and duct segments, or other components that are to be blasted with media). Further, while the disclosure illustrates the masking systems with reference to a shot peening process, the masking systems disclosed herein may be used in association with other processes such as grit blasting, sand blasting, or other processes requiring selective masking of a component.

Many different arrangements of the various components depicted, as well as components not shown, are possible without departing from the spirit and scope of the present disclosure. Embodiments of the present disclosure have been described with the intent to be illustrative rather than restrictive. Alternative embodiments will become apparent to those skilled in the art that do not depart from its scope. A skilled artisan may develop alternative means of implementing the aforementioned improvements without departing from the scope of the present disclosure.

It will be understood that certain features and subcombinations are of utility and may be employed without reference to other features and subcombinations and are contemplated within the scope of the claims. Not all steps listed in the various figures need be carried out in the specific order described.

The disclosure claimed is:

1. A masking system for selectively masking a component, the masking system comprising:
a mask carrier having a first carrier section and a second carrier section; and
an insert configured to retain the component, the insert having a first insert section and a second insert section, the first insert section and the first carrier section having a first connector set, the first insert section and the second insert section having a second connector set, the first connector set extending in a first direction and removably coupling the first insert section to the first carrier section, the second connector set extending in a second direction oblique to the first direction and removably coupling the first insert section to the second insert section.

2. The masking system of claim 1, wherein the first connector set includes a first connector and a second connector, the first connector being part of the first carrier section and the second connector being part of the first insert section.

3. The masking system of claim 2, wherein the second connector set includes a third connector and a fourth connector, the third connector being part of the first insert section and the fourth connector being part of the second insert section.

4. The masking system of claim 3, further including a third connector set associated with each of the first carrier section and the second carrier section, the third connector set extending in the second direction and removably coupling the first carrier section to the second carrier section.

5. The masking system of claim 4, further including a fourth connector set associated with the second insert section and the second carrier section, the fourth connector set extending in the first direction and removably coupling the second insert section to the second carrier section.

6. The masking system of claim 1, wherein the first connector set has a male component and a female component.

7. The masking system of claim 1, further including a tongue disposed on the first carrier section and a complementary groove disposed on the second carrier section.

8. The masking system of claim 1, wherein the first carrier section is additively manufactured.

9. The masking system of claim 1, configured to selectively mask the component for a shot peening process.

10. The masking system of claim 1, wherein the component is a gas turbine component.

11. The masking system of claim 10, wherein the gas turbine component is a vane.

12. The masking system of claim 10, wherein the insert is configured to retain the gas turbine component only in one orientation.

13. The masking system of claim 1, wherein the first carrier section has a semi-cylindrical base and an insert support.

14. A masking system for selectively masking a component, the masking system comprising:
an insert having a first insert section and a second insert section; and
a mask carrier having a first carrier section and a second carrier section, the first carrier section and the second carrier section having a first connector set, the first carrier section and the first insert section having a second connector set, the first connector set extending in a first direction and removably coupling the first carrier section to the second carrier section, the second connector set extending in a second direction disparate from the first direction and removably coupling the first carrier section to the first insert section.

15. The masking system of claim 14, wherein the first insert section has a convex projection, and the second insert section has a concave channel.

16. The masking system of claim 14, wherein the first insert section has a tongue, and the second insert section has a complementary groove.

17. The masking system of claim 14, wherein the first direction is oblique to the second direction.

18. A masking system for selectively masking a component for a shot peening process, the masking system comprising:
a mask carrier having a first carrier section and a second carrier section; and
an insert configured to retain the component, the insert having a first insert section and a second insert section, the first insert section and the first carrier section having a first connector set, the first insert section and the second insert section having a second connector set, the first connector set extending in a first direction and removably coupling the first insert section to the first carrier section, the second connector set extending in a second direction oblique to first direction and removably coupling the first insert section to the second insert section.

19. The masking system of claim 18, wherein an outermost diameter of the mask carrier is oversized relative to an interior diameter of a can of a shot peen device.

20. The masking system of claim 18, wherein the component is a gas turbine component.
